(19) United States
(12) Patent Application Publication
(10) Pub. No.: US 2025/0210411 A1
(43) Pub. Date: Jun. 26, 2025

(54) INTERCONNECT LAYERS WITH AIR GAPS

(71) Applicant: Intel Corporation, Santa Clara, CA (US)

(72) Inventors: Ananya Dutta, Portland, OR (US); Akshit Peer, Hillsboro, OR (US); Ryan Pearce, Beaverton, OR (US); Sreenivas Kosaraju, Portland, OR (US); Ece Alat, Cornelius, OR (US); Sudipto Naskar, Portland, OR (US); Jeffery Bielefeld, Forest Grove, OR (US); Mauro J. Kobrinsky, Portland, OR (US)

(73) Assignee: Intel Corporation, Santa Clara, CA (US)

(21) Appl. No.: 18/395,910

(22) Filed: Dec. 26, 2023

(51) Int. Cl. H01L 21/768; H01L 23/522; H01L 23/532

(52) U.S. Cl. CPC H01L 21/7682; H01L 21/76802; H01L 23/5226; H01L 23/53252

(57) ABSTRACT

In a metallization layer of an integrated circuit device, air gaps are formed between adjacent metal lines, e.g., between high aspect ratio metal lines at tight pitches, to reduce the capacitance between the metal lines. A deposition process for a dielectric material between metal lines is tuned so that air gaps are formed within the dielectric material, in areas between metal lines. The dielectric material is also deposited between the upper portions of the metal lines, closing the air gaps from the top. The dielectric material is highly selective to a subsequent via etch, so that the dielectric material near the tops of the metal lines acts as an etch stop and prevents punch through into the air gaps.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each IC die, including devices and interconnects, becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C illustrate different cross sections of an IC device having a device layer and multiple metal layers, according to some embodiments of the present disclosure.

FIG. 2 is a flow diagram of a process for fabricating a metal layer with air gaps between metal lines, according to some embodiments of the present disclosure.

FIG. 3 is a cross-section of metal lines within a metal layer, according to some embodiments of the present disclosure.

FIG. 4 is a cross-section illustrating deposition of a dielectric material with air gaps, according to some embodiments of the present disclosure.

FIG. 5 is a cross-section illustrating wafer polishing after the dielectric deposition of FIG. 4, according to some embodiments of the present disclosure.

FIG. 6 is a cross-section illustrating the deposition of a dielectric layer over the metal layer, according to some embodiments of the present disclosure.

FIG. 7 is a cross-section illustrating a via etch in the dielectric layer, according to some embodiments of the present disclosure.

FIG. 8 is a cross-section illustrating via deposition over one of the metal lines, according to some embodiments of the present disclosure.

FIG. 9 is a cross-section illustrating a first alternate embodiment of a metal layer with air gaps between metal lines, according to some embodiments of the present disclosure.

FIG. 10 is a cross-section illustrating a second alternate embodiment of a metal layer with air gaps between metal lines, according to some embodiments of the present disclosure.

FIGS. 11A and 11B are top views of a wafer and dies that include one or more metal layers with air gaps between metal lines accordance with any of the embodiments disclosed herein.

FIG. 12 is a cross-sectional side view of an IC device that may include one or more metal layers with air gaps between metal lines in accordance with any of the embodiments disclosed herein.

FIG. 13 is a cross-sectional side view of an IC device assembly that may include metal layers with air gaps between metal lines in accordance with any of the embodiments disclosed herein.

FIG. 14 is a block diagram of an example computing device that may include one or more metal layers with air gaps between metal lines in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

An IC device includes various circuit elements, such as transistors and capacitors, coupled together by metal interconnects. The circuit elements and metal interconnects may be formed in different layers. In particular, one or more layers of an IC device in which transistors and other IC components are implemented may be referred to as a “transistor layer” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. In general, the transistor layer and the metal layers may be provided in any layers of an IC device as long as they are in different planes (e.g., at different distances from) a support structure (e.g., a die, a chip, a substrate, a carrier substrate, or a package substrate) of the IC device, or some other reference plane.

Typically, an IC device includes a metallization stack, which is a collection of several metal layers, stacked above one another, in which different interconnects are provided. The interconnects include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided, and the via may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” where the term “interconnect” may be used to describe any element formed of an electrically conductive material for providing electrical connectivity to/from one or more components associated with an IC or/and between various such components.

As noted above, there is a drive to reduce the feature size and increase density on IC chips. As transistor sizes decrease, the metal lines in metal layers formed over the device layer are correspondingly denser. For example, pitches between adjacent metal lines are reduced so that connections to and between the transistors can be provided in the metallization layers. To produce narrow metal lines at tighter pitches, different materials and fabrication methods are being explored. For example, ruthenium (Ru) can be formed into high aspect ratio metal lines with tight pitches, e.g., with pitches of 20 nanometers or less, using subtractive patterning methods. However, tight, high-aspect ratio metal lines are subject to capacitance between the metal lines, which reduces overall device performance.

Typically, a dielectric material is between the metal lines in a metal layer. Capacitance is proportional to the dielectric constant or relative permittivity of the material between parallel plates, e.g., two parallel metal lines in a metal layer, with materials having a higher dielectric constant resulting in greater capacitance. Reducing the dielectric constant reduces the capacitance between metal lines. Silicon dioxide is a common dielectric material that has a dielectric constant of 3.9. Air gaps, with a dielectric constant of around 1, dramatically reduce capacitance relative to common dielectric materials.

However, leaving an air gap between metal lines creates a risk of punch-through when vias are etched and formed over the metal lines. If the via material is deposited in the area between the metal lines, this can create an unwanted short. To avoid this, air gaps may not be included in regions where vias are placed. However, in these regions, capacitance can still be a problem. Furthermore, forming air gaps only in certain regions of a wafer or die involves a lithography process that can add cost and time, and potentially lead to defects. Alternatively, an additional dielectric layer (e.g., a via etch stop film) may be provided over the air gaps, where the dielectric layer protects the air gaps below. However, this requires additional processing steps, and again, can lead to defects if the via etch stop is not etched directly over the metal lines.

As disclosed herein, air gaps are formed between metal lines, e.g., between high aspect ratio metal lines at tight pitches (e.g., pitches less than 20 nanometers, less than 15 nanometers, or less than 10 nanometers), to reduce the capacitance between the metal lines. The deposition process is tuned such that air gaps are formed within dielectric material that is deposited between the metal lines, e.g., along the walls of the metal lines, and the dielectric material is also deposited between the upper portions of the metal lines. The dielectric material is highly selective to the via etch, so that the dielectric material near the tops of the metal lines acts as an etch stop and prevents punch through into the air gaps. In some examples, the dielectric material includes aluminum, which is typically resistant to via etch materials.

The metal layers with air gaps between metal lines described herein may be implemented in one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

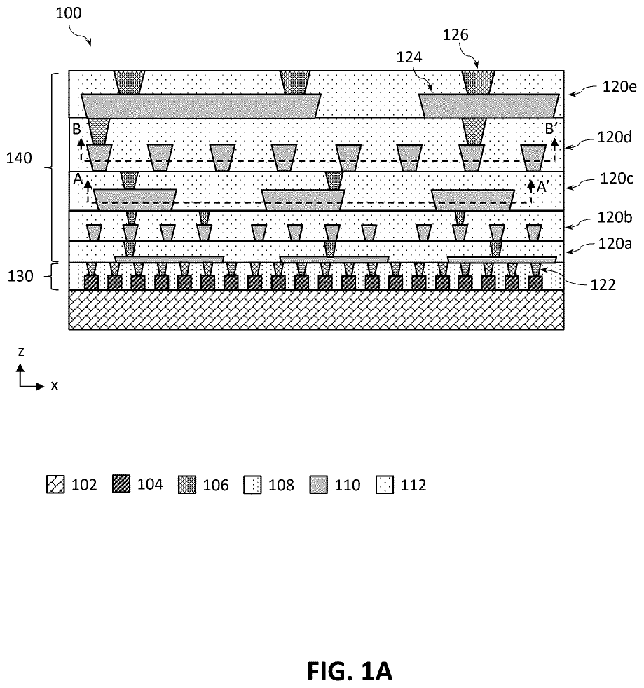

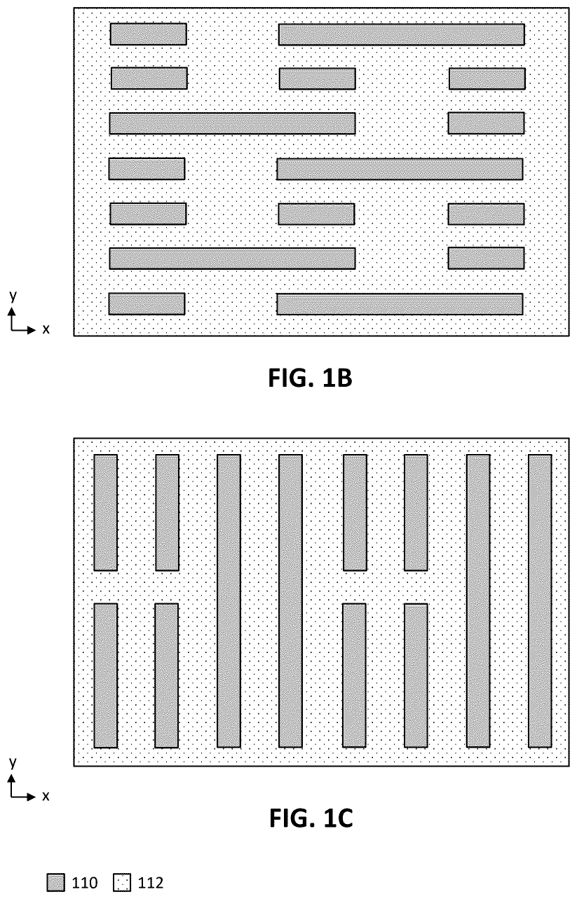

For convenience, if a collection of drawings designated with different letters are present, e.g., FIGS. 1A-1B, such a collection may be referred to herein without the letters, e.g., as “FIG. 1.”

Example IC Device with Device Layer and Metal Layers

FIGS. 1A-1C illustrate different cross sections of an IC device 100 having a device layer and multiple metal layers, according to some embodiments of the present disclosure. One or more of the metal layers may include air gaps, as described herein. FIG. 1A provides a first cross-section in an x-z plane. FIGS. 1B and 1C provide two cross-sections through the x-y plane. FIG. 1B is a cross-section through the plane AA′ in FIG. 1A, and FIG. 1C is a cross-section through the plane BB′ in FIG. 1A.

A number of elements referred to in the description of FIGS. 1A-1C and 3-10 with reference numerals are illustrated in these figures with different patterns, with a legend showing the correspondence between the reference numerals and patterns being provided at the bottom of the drawing pages. For example, the legend in FIG. 1A illustrates that FIG. 1A uses different patterns to show a support structure 102, logic devices 104, a first conductive material 106, a first dielectric material 108, a second conductive material 110, and a second dielectric material 112.

FIG. 1A illustrates cross sections of a device layer 130 and a metallization stack 140. The device layer 130 is over a support structure 102. In this example, the device layer 130 includes logic devices 104, e.g., transistors. In some embodiments, the logic devices 104, or a portion of the logic devices 104, are logic transistors in a compute logic layer or compute logic region. In some embodiments, the logic devices 104, or a portion of the logic devices, are access transistors in a memory layer, e.g., transistors that provide access to capacitor-based memory. In some embodiments, the logic devices 104 may provide transistor-based memory, such as static random-access memory (SRAM), which uses transistors arranged as latches, also referred to as flip-flops, to store data. In some embodiments, the device layer 130 and/or additional layers above or below the device layer 130 may include additional or alternative types of devices, such as capacitors, inductors, waveguides, etc.

The logic devices 104 may include a wide variety of configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. As shown in FIG. 1A, at least a portion of the logic devices 104 may be coupled to interconnect structures in the metallization stack 140. For example, the logic devices 104 may be semiconductor devices (e.g., transistors) coupled to contacts formed from the first conductive material 106 (e.g., source, drain, and/or gate contacts). The via 122 is an example of a contact to a logic device 104.

The metallization stack 140 includes multiple metal layers 120a-120e, where 120a is the lowermost metal layer over the device layer 130, and the metal layer 120e is the uppermost metal layer. While five metal layers 120a, 120b, 120c, 120d, and 120e are illustrated in FIG. 1A, an IC device may have fewer or more metal layers, e.g., up to 10 metal layers, up to 15 metal layers, or more. In addition, while metal layers 120 are on one side of the device layer 130, in other embodiments, metal layers may be included on both sides of the device layer 130, e.g., on the front side and the back side.

Each metal layer 120 includes conductive structures, including metal lines or trenches (e.g., the line 124) formed from the second conductive material 110 and vias (e.g., the via 126) formed from the first conductive material 106. While FIG. 1 illustrates a first conductive material 106 for the vias and a second conductive material 110 for the metal lines, at each metal layer, any suitable conductive material may be used. For example, in a given layer, the same conductive material may be used for both metal lines and vias. As another example, in different layers, different materials may be used for the metal lines and/or vias, e.g., ruthenium may be included in the metal lines in the metal layer 120a, while copper is included in the metal lines in the metal layer 120d. In various embodiments, conductive structures may include multiple conductive materials, e.g., a first metal as a liner, and a second metal as a fill.

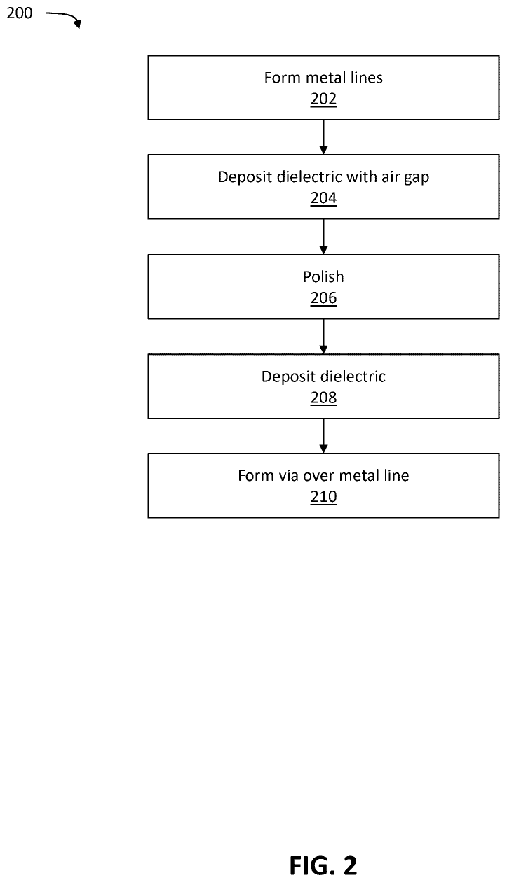

The logic devices 104 are surrounded by a first dielectric material 108 in the device layer 130. The metal lines and vias in the metal layers 120a-120e are surrounded by a second dielectric material 112. In some embodiments, the dielectric materials 108 and 112 may be the same. In some embodiments, different dielectric materials may be included in different ones of the metal layers, e.g., the metal layer 120a may include a different dielectric material from the metal layer 120d. In some embodiments, multiple dielectric materials may be present in a given layer. As described with respect to FIGS. 2-10, air gaps may be included between metal lines in at least a portion of the metal layers 120a-120e.

More generally, the dielectric materials 108 and 112 may include low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In addition, the conductive materials 106 and 110 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, conductive materials 106 and 110 may include one or more electrically conductive alloys, oxides, or carbides of one or more metals. The conductive materials 106 and 110 may form conductive pathways to route power, ground, and/or signals to/from various components of the logic layer 130. The arrangement of the conductive materials 106 and 110 in FIG. 1 is merely illustrative, and the conductive pathways formed by the conductive materials 106 and 110 may be connected to one another in any suitable manner.

The support structure 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the support structure 102 may be formed are described here, any material that may serve as a foundation upon which an IC device as described herein may be built falls within the spirit and scope of the present disclosure.

FIGS. 1B and 1C illustrate cross-sections through two example metal layers 120c and 120d. The metal lines in a given metal layer are generally elongated structures that extend primarily in one direction within the metal layer. Typically, this direction is substantially parallel to the or perpendicular to the arrangement of the logic devices in the device layer 130, and is either perpendicular or parallel to different edges of the support structure 102, in particular, being either perpendicular or parallel to different edges of the front face or the back face of the support structure. At different metal layers 120, the metal lines may extend in different directions. For example, in the metal layer 120c, the metal lines extend in the x-direction in the coordinate system shown in FIG. 1, as illustrated in FIG. 1B. In the metal layer 120d, the metal lines extend in the y-direction in the coordinate system shown in FIG. 1 (i.e., perpendicular to the metal lines in metal layer 120c), as illustrated in FIG. 1C.

The air gaps, where present in a metal layer, generally extend in parallel to the metal lines. For example, in the metal layer 120c, air gaps may extend in the x-direction between adjacent metal lines (which also extend in the x-direction), and in the metal layer 120d, air gaps may extend in the y-direction between adjacent metal lines (which also extend in the y-direction).

Example Process for a Metal Layer with Air Gaps

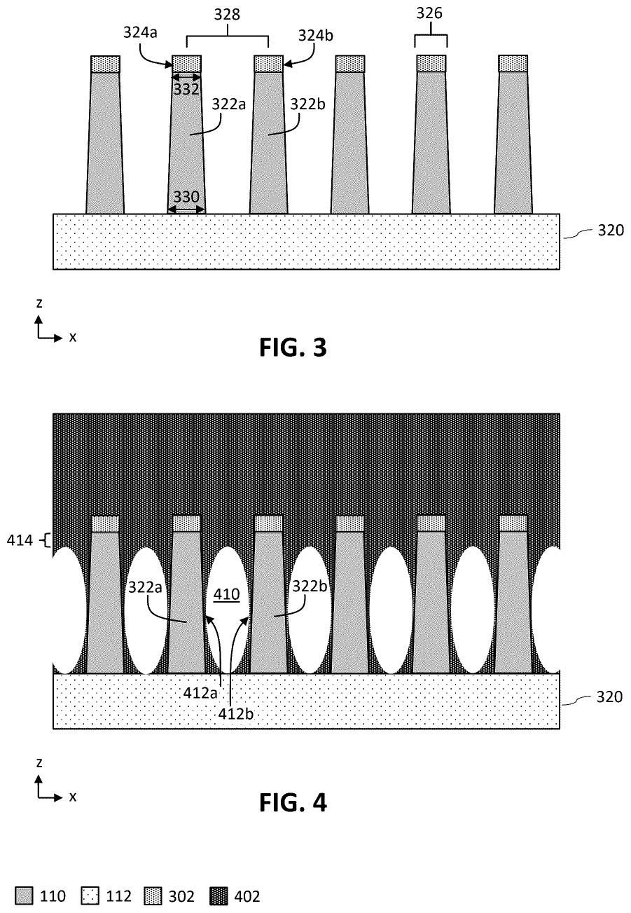

FIG. 2 is a flow diagram of a process for fabricating a metal layer with air gaps between metal lines, according to some embodiments of the present disclosure. FIGS. 3-8 illustrate various steps in the processing method 200 of FIG. 2, according to some embodiments of the present disclosure. In general, the processing method 200 is performed across a wafer, with many individual metal lines and air gaps formed on the wafer. In addition, the processing method 200 may be performed multiple times on a wafer, e.g., in different metal layers (e.g., the metal layers 120c and 120d of FIG. 1). FIGS. 3-8 illustrate cross-sections of processing steps across several metal lines in one example metal layer. The processing method 200 describes a process of providing air gaps between metal lines and vias over the metal lines. Additional steps may be performed before, during, and/or after the process 200 to produce an IC device that includes the air gaps described herein.

At 202, a process for forming metal lines is performed. For example, metal lines may be formed using subtractive process. In a subtractive process, a material is deposited or transferred onto an area (e.g., a wafer or die), and portions of the material are removed, such that the remaining material has a desired pattern. For example, to form metal lines using a subtractive process, a metal is deposited across a region, and a resist material is deposited over top of the metal. The resist may be patterned based on a design for a particular pattern for the metal lines. The resist may be patterned using any known technique, e.g., by lithographically patterning the resist, and etching portions of the resist. After patterning the resist, portions of the metal that are exposed by the patterned resist are removed using an etching process. The remaining resist may removed, or removed at a later time.

FIG. 3 is a cross-section of metal lines within a metal layer, according to some embodiments of the present disclosure. In this example, a series of metal lines 322, including adjacent metal lines 322a and 322b, are formed over a layer 320. In this illustration, the layer 320 includes the second dielectric material 112, and the layer 320 may correspond to one of the metal layers 120 of FIG. 1. For example, the layer 320 may be the metal layer 120a, and FIGS. 3-8 illustrate the formation of the metal layer 120b. Alternatively, the layer 320 may correspond to the device layer 130 of FIG. 1A, and FIGS. 3-8 illustrate the formation of the metal layer 120a.

The metal lines 322 include the second conductive material 110. In some embodiments, the second conductive material 110 includes ruthenium. In other embodiments, the second conductive material 110 includes copper, tungsten, molybdenum, nickel, and/or aluminum, or any of the other conductive materials or combination of materials described with respect to FIG. 1. In some other specific embodiments, the second conductive material 110 for the metal lines 322 may include rhodium; iridium; cobalt; nickel and aluminum (e.g., NiAl); cobalt and tin (e.g., CoSn); platinum, cobalt, and oxygen (e.g., PdCoO₂); palladium, cobalt, and oxygen (e.g., PdCoO₂); molybdenum and phosphorus (e.g., MoP); niobium and arsenic (e.g., NbAs); chromium, aluminum, and carbon (e.g., Cr₂AlC); molybdenum and boron (e.g., MnB); or cerium, cobalt, and indium (e.g., CeCoIn₅).

In this layer, the metal lines extend in the y-direction (i.e., into or out of the page) in the coordinate system shown. The width 326 may represent an average width of a metal line 322, or a width at a midpoint (in the z-direction) of the metal line, where width is measured in the x-direction. The metal lines 322 may have a width 326 of, for example, between 1 and 3 nanometers (nm), between 2 and 5 nm, between 5 and 10 nm, between 10 and 20 nm, between 20 and 30 nanometers, between 30 and 50 nanometers, or a different width or range of widths. In some embodiments, different metal lines 322 may have different widths. The metal lines 322 may have a height in the z-direction of, e.g., 10-100 nm. As illustrated in FIG. 1, in general, at higher layers (e.g., farther from the device layer 130), the metal lines have greater heights and widths than at lower layers (e.g., layers closer to the device layer 130).

The pitch 328 illustrates an average pitch between two adjacent metal lines, where pitch refers to the center-to-center distance between closest adjacent structures, e.g., the illustrated pitch 328 is a center-to-center distance between the metal lines 322a and 322b. The pitch may be, for example, less than 50 nm or less than 20 nm, e.g., between 5 and 10 nm, between 10 and 20 nm, between 20 and 40 nanometers, between 30 and 50 nanometers, or a different pitch or range of pitches. In some embodiments, different sets of metal lines 322 may be arranged at different pitches. As illustrated in FIG. 1, in general, at higher layers (e.g., farther from the device layer 130), the metal lines have greater pitches than at lower layers (e.g., layers closer to the device layer 130). In some examples, the air gaps disclosed herein may be in one or more lower layers (e.g., one or more of the first five metal layers over a device layer 130) while the air gaps may not be included in one or more upper layers (e.g., the sixth or subsequent metal layers over the device layer), as capacitance within in the upper metal layers, which typically have more widely spaced metal lines, tends to be lower.

In this example, a resist material 302 is over the metal lines 322, e.g., the resist 324a is over the metal line 322a, and the resist 324b is over the metal line 322b. The resist material 302 may be a hard mask. The metal lines in FIG. 3 may have been formed using subtractive processing, as described above. In other embodiments, the resist 324 is removed after the metal lines 322 are etched.

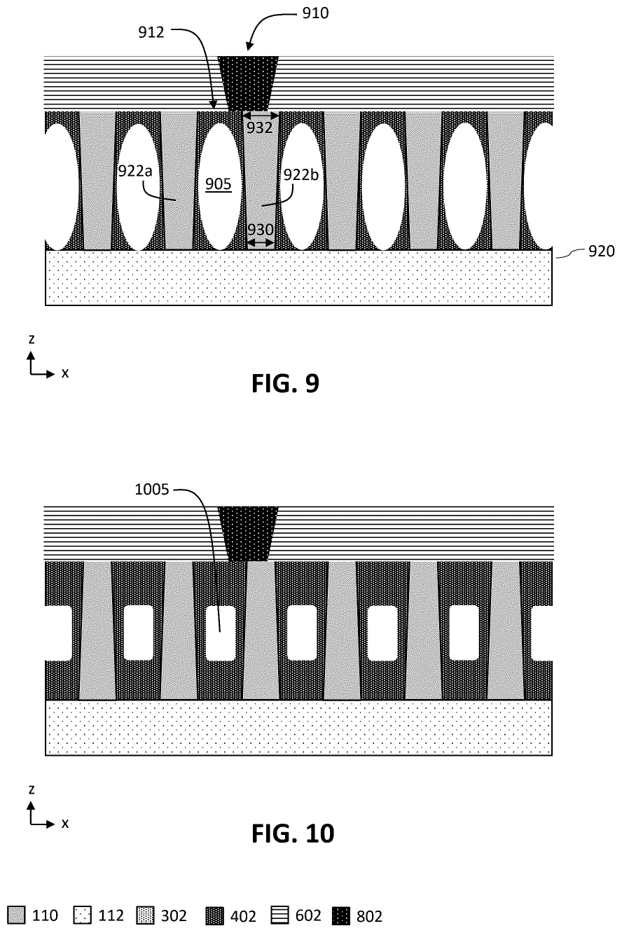

When subtractive processing is used, the metal lines 322 may taper (i.e., become increasingly narrow) in an upward direction in the cross-section and orientation shown in FIG. 3. For example, a width 330 of the metal line 322a at a lower portion of the metal line 322a (e.g., along an upper surface of the layer 320 under the metal line 322a) is wider than a width 332 of the metal line 322b at the upper portion of the metal line 322a (e.g., under the resist 324a). In other examples, a subtractive process may not be used; an example metal layer produced without subtractive processing is shown in FIG. 9.

Returning to FIG. 2, at 204, a dielectric with air gaps is deposited between the metal lines. The dielectric material may be deposited in a single deposition process in a manner that results in air gaps between adjacent metal lines. For example, an atomic layer deposition (ALD) process may be used. ALD is a thin film deposition technique that uses precursors that react with exposed surfaces. ALD can allow for relatively slow and well-controlled deposition of the dielectric material. The ALD parameters, such as bias and duration, may be tuned so that the dielectric material is deposited along the walls of the metal lines and then closes over areas between adjacent metal lines, partially filling in a space near the tops of the metal lines while leaving an air gap between the metal lines. The deposition process may be applied across the device, e.g., across a die or wafer, and may not involve lithographic steps, e.g., to mask off certain regions.

FIG. 4 is a cross-section illustrating deposition of a dielectric material with air gaps, according to some embodiments of the present disclosure. A dielectric material 402 has been deposited over the metal lines 322 and some of the dielectric material 402 is deposited between the metal lines 322, e.g., between the adjacent metal lines 322a and 322b. A first layer 412a of the dielectric material 402 is deposited on a first side wall of the metal line 322a, and a second layer 412b of the dielectric material 402 is deposited on a second side wall of the metal line 322b. The layers 412a and 412b of dielectric material 402 along the metal lines 322 may, at a narrowest or thinnest portion, have a width of, e.g., less than 5 nm, less than 3 nm, less than 2 nm, less than 1 nm, between 1 and 5 nm, less than 0.8 nm, less than 0.5 nm, between 0.5 and 1 nm, less than 0.3 nm, less than 0.2 nm, less than 0.1 nm, between 0.1 and 1 nm, or another width or range of widths. A series of air gaps, such as air gap 410, are formed within the dielectric material 402 and between adjacent metal lines 322. For example, the air gap 410 is between the metal lines 322a and 322b, and bounded on the left and right sides by the layers 412a and 412b of dielectric material 402. The air gap 410 may include minimal or no material (i.e., the air gap 410 may be vacuum or substantially a vacuum), or the air gap 410 may be filled with a gaseous substance, e.g., nitrogen gas or a different gas.

The dielectric material 402 fully or partially surrounds the air gaps. A portion 414 of dielectric material 402 is between the tops of the metal lines 322 and the tops of the air gaps, e.g., the top of the air gap 410. The portion 414 may have a height measured in the z-direction of, e.g., at least 2 nm, at least 3 nm, at least 5 nm, at least 10 nm, e.g., between 2 and 50 nm or within a smaller range, e.g., 2-5 nm, 5-10 nm, 10-30 nm, or 20-50 nm. The portion 414 protects the air gap 410 to prevent punch through during via formation. In this example, the air gap 410 extends downward to the top of the layer 320; in this example, the dielectric material 402 may not fully surround the air gap 410, but rather, mostly surrounds the air gap 410, while a portion of the air gap 410 is bounded by the layer 320. In other embodiments, a layer of the dielectric material 402 may be between the air gap 410 and the layer 320; in such embodiments, the dielectric material 402 may fully surround the air gap 410.

In this example, the air gap 410 has a generally oval shape. In other examples, the air gap 410 may have a different shape, e.g., a stadium shape, a circular shape, a rounded rectangle, etc.

The dielectric material 402 is selected to be highly selective to the etch chemistry used to etch vias over the metal lines 322. In some embodiments, the dielectric material 402 includes aluminum. The dielectric material 402 may include other materials, such as silicon and one or more of oxygen, nitrogen, and carbon, in addition to aluminum. In some embodiments, aluminum is not included in the dielectric material 402.

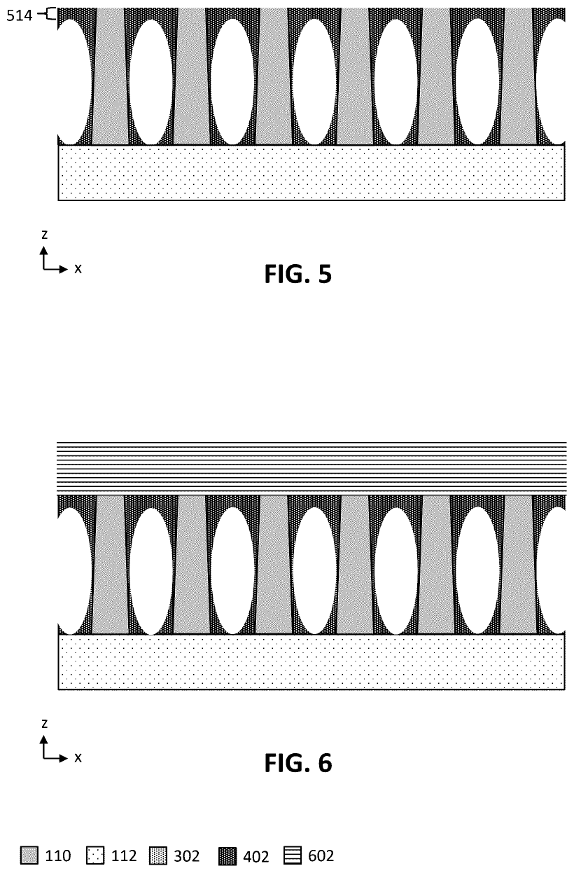

Returning to FIG. 2, at 206, the top surface is polished to expose the tops of the metal lines. FIG. 5 is a cross-section illustrating wafer polishing after the dielectric deposition of FIG. 4, according to some embodiments of the present disclosure. As shown in FIG. 5, following the polishing process, the dielectric material 402 and resist material 302 (e.g., the hard mask) over the metal lines 322 has been removed, exposing the metal lines 322 at an upper face. A portion 514 of the portion 414 of the dielectric material 402 remains over the air gaps. The portion 514 may have a height equal to or less than the height of the portion 414. The portion 514 may be at least 2 nm thick, e.g., any of the heights or ranges described with respect to the portion 414. The height of the air gap 410 (measured in the z-direction) is less than the height of the metal lines 322 after polishing.

At 208, a dielectric layer is deposited over the upper surface, including over the tops of the metal lines 322 and over the portion 514 of the dielectric material. The dielectric layer may include any suitable dielectric material for forming vias, e.g., any of the dielectric materials described with respect to FIG. 1. FIG. 6 is a cross-section illustrating the deposition of a dielectric layer 602 over the metal layer, according to some embodiments of the present disclosure. The dielectric layer 602 may have a different composition from the dielectric material 402. For example, in one embodiment, the dielectric material 402 includes aluminum, and the dielectric layer 602 does not include aluminum.

At 210, a process for forming a via over a metal line is performed. For example, a via hole may be etched in the dielectric layer using a lithographic process, and the via hole may be filled with a conductive material to form a via.

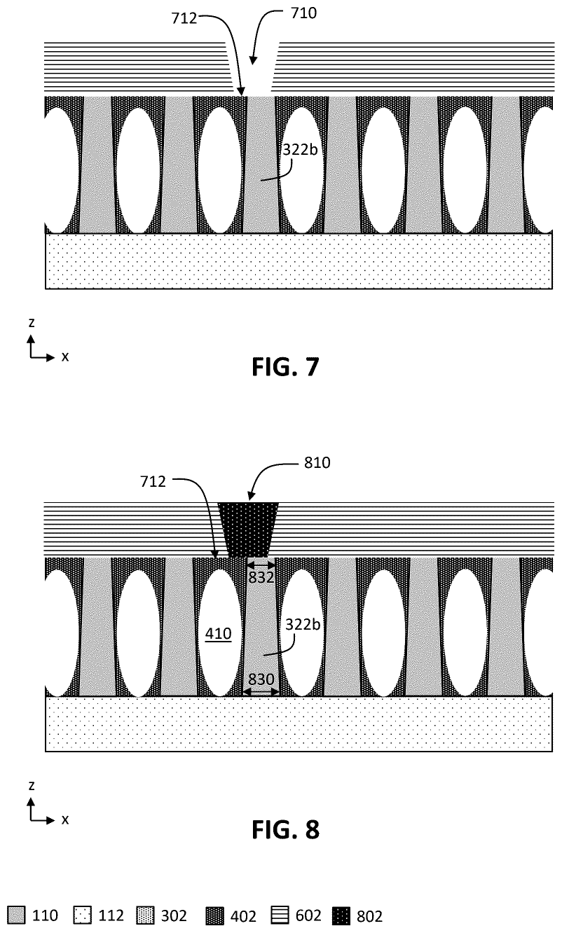

FIG. 7 is a cross-section illustrating a via etch in the dielectric layer, according to some embodiments of the present disclosure. A via hole 710 is formed within the dielectric layer 602, exposing a portion of the upper surface of the metal line 322b. In this example, the via hole 710 is not perfectly aligned to the metal line 322b, and a portion of the via hole is over the dielectric material 402. It can be difficult to perfectly place via holes over tightly pitched metal lines, leading to some amount of offset, as illustrated in FIG. 7. Despite the misalignment, a portion 712 of the dielectric material 402 over the air gap 410 prevents the via hole 710 from reaching into the air gap 410, thus protecting the air gap from the via material subsequently deposited. The portion 712 of the dielectric material corresponds to the portion 514 of dielectric material over the air gap 410.

FIG. 8 is a cross-section illustrating via deposition over one of the metal lines, according to some embodiments of the present disclosure. A conductive material 802 is deposited into the via hole 710, forming a via 810. The conductive material 802 may be the first conductive material 106 of FIG. 1, described above. As noted with respect to FIG. 7, the portion 712 of the dielectric material 402 over the air gap 410 prevented the conductive material 802 from entering the air gap 410.

As described with respect to FIG. 3, in this example, the metal lines 322 taper in an upward direction, e.g., towards the dielectric layer 602 over the metal lines 322, and widen in the direction of lower layers, e.g., the layer 320 and/or the device layer 130, in the cross-section shown in FIG. 3. In the resulting metal layer, a width 830 at a lower portion of the metal lines (e.g., a width at or near the base of the metal line 322b over the layer 320) is wider than a width 832 at an upper portion of the metal lines, e.g., under the via 810 over the metal line 322b. The via 810 may taper in an opposite direction, with the via 810 being narrower at the interface with the metal line 322a, and wider at an upper portion, e.g., a portion in contact with the next metal layer formed over the metal layer illustrated in FIG. 8.

Alternate Arrangements of Metal Layers with Air Gaps

In the example shown in FIGS. 3-8, the metal lines 322 were formed using subtractive processing. As noted above, in other examples, a subtractive process may not be used; instead, a sacrificial material may be patterned and etched, the metal lines 322 deposited in the etched regions, and the sacrificial material removed. The dielectric regions with air gaps are then formed in the areas around the metal lines, in a similar manner to processes 204-210 of FIG. 2.

FIG. 9 is a cross-section illustrating a first alternate embodiment of a metal layer with air gaps between metal lines, according to some embodiments of the present disclosure. FIG. 9 is similar to FIG. 8 except for the shape of the metal lines 922. FIG. 9 includes metal lines 922 formed from the second conductive material 110, and the dielectric material 402 with air gaps formed therein. For example, the air gap 905 is formed within dielectric material 402 between the metal lines 922a and 922b. The arrangement of the dielectric material 402 and air gaps (e.g., the air gap 905) is similar to the arrangement described with respect to FIGS. 2-8. The metal lines 922 and dielectric material 402 are over a layer 920, which is similar to the layer 320. A dielectric layer 602 is over the metal lines 922 and dielectric material 402, and a via 910 is within the dielectric layer 602 and coupled to the metal line 922b, similar to the dielectric layer 602 and via 810 described above.

In this example, the metal lines 922 taper in the direction of lower layers, e.g., the layer 920 and/or the device layer 130, and the metal lines 922 widen in the direction of upper layers, e.g., the dielectric layer 602. A width 930 at a lower portion of the metal lines (e.g., a width at or near the base of the metal line 922b over the layer 920) is narrower than a width 932 at an upper portion of the metal lines, e.g., under the via 910 over the metal line 922b. The via 910 may taper in the same direction as the metal lines, with the via 910 being narrower in a lower portion, e.g., at the interface with the metal line 922a, and wider at an upper portion, e.g., a portion in contact with the next metal layer formed over the metal layer illustrated in FIG. 9.

The air gaps illustrated in FIGS. 4-9 are fairly large, e.g., extending nearly to the sides of the metal lines and to the layer 320 or 920 below the metal lines. In other examples, the air gaps may have different shapes and different sizes. FIG. 10 is a cross-section illustrating a second alternate embodiment of a metal layer with air gaps between metal lines, according to some embodiments of the present disclosure. FIG. 10 illustrates a metal layer similar to the metal layer shown in FIG. 8 and described above, but the air gaps, such as air gap 1005, have a different shapes and sizes from the air gaps (e.g., air gap 410) of FIG. 8. For example, the air gap 1005 has an overall smaller cross-section and, correspondingly, smaller volume than the air gap 410. More generally, the ratio between the volume of air and the dielectric material between the metal lines in FIG. 8 is greater than the corresponding ratio in FIG. 10. Said another way, the air gaps in FIG. 8 are relatively larger to the metal lines than the air gaps in FIG. 10, which are relatively smaller compared to the metal lines. In addition, while the air gaps in FIG. 8 had oval shapes, the air gaps in FIG. 10 have rounded rectangle shapes.

### Example Devices

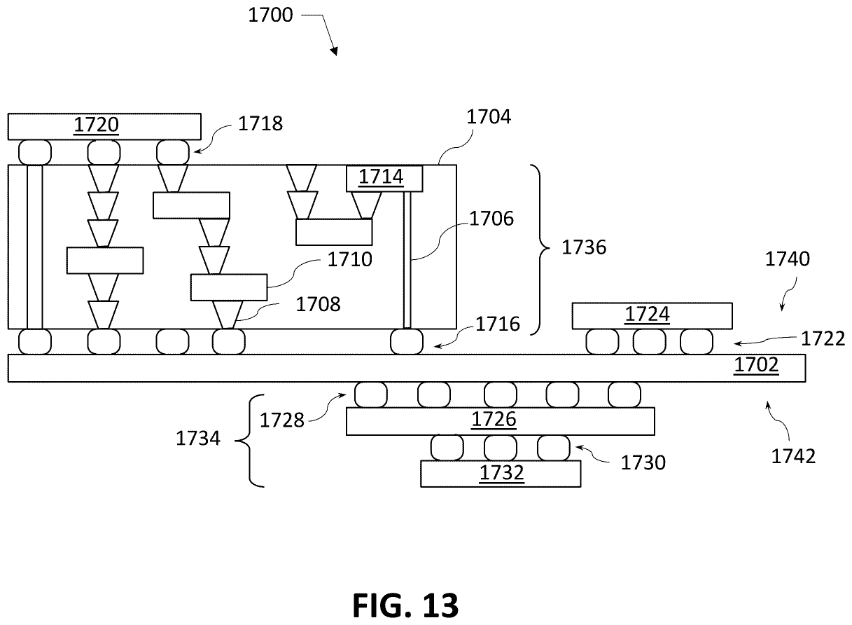

The circuit devices with one or more metal layers with air gaps between metal lines disclosed herein may be included in any suitable electronic device. FIGS. 13-16 illustrate various examples of apparatuses that may include the one or more transistors disclosed herein, which may have been fabricated using the processes disclosed herein.

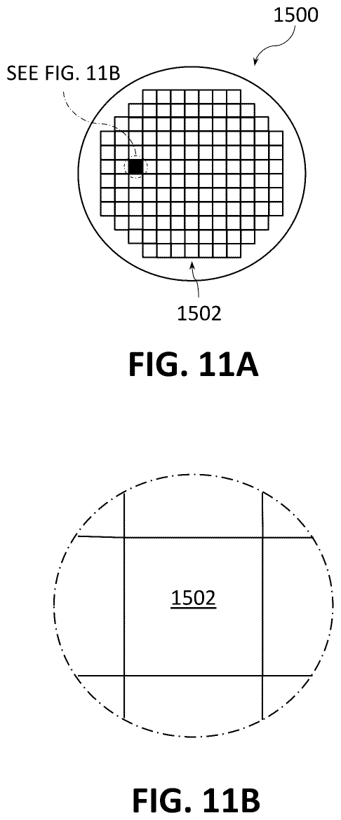

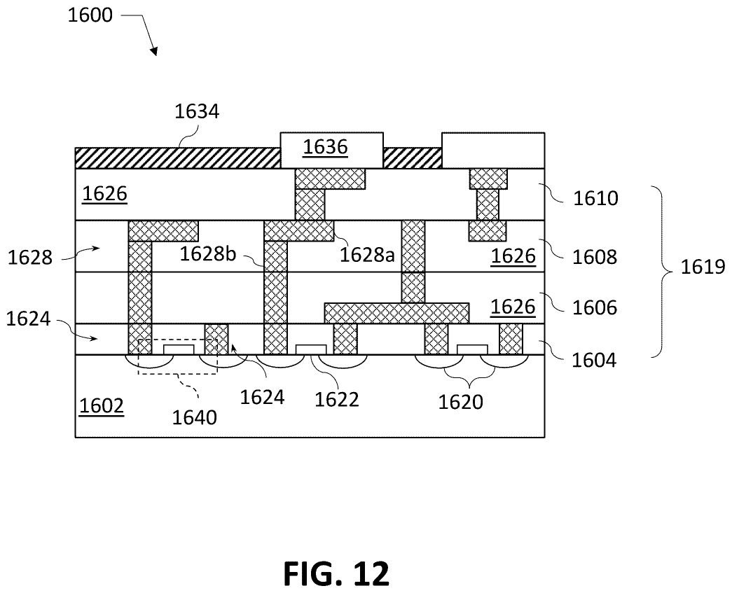

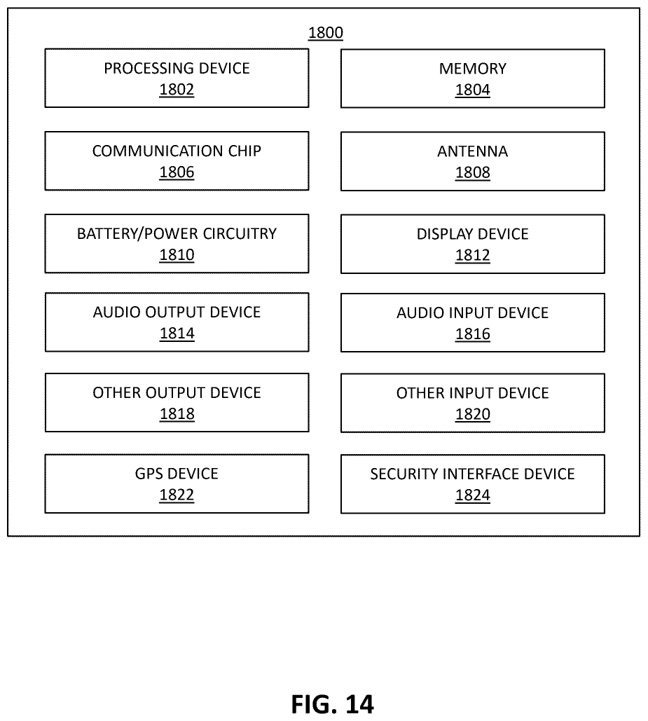

FIGS. 11A and 11B are top views of a wafer and dies that include one or more IC structures including one or more metal layers with air gaps between metal lines in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 3-10, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 12, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

FIG. 12 is a cross-sectional side view of an IC device 1600 that may include one or more metal layers with air gaps between metal lines in accordance with any of the embodiments disclosed herein. The IC device 1600 may be formed on a substrate 1602 (e.g., the wafer 1500 of FIG. 11A) and may be included in a die (e.g., the die 1502 of FIG. 11B). The substrate 1602 may be any substrate as described herein. The substrate 1602 may be part of a singulated die (e.g., the dies 1502 of FIG. 11B) or a wafer (e.g., the wafer 1500 of FIG. 11A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more metal layers with air gaps between metal lines at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 12 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 12). Although a particular number of interconnect layers 1606-1610 is depicted in FIG. 12, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 12. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 12. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

FIG. 13 is a cross-sectional side view of an IC device assembly 1700 that may include components having or being associated with (e.g., being electrically connected by means of) one or more metal layers with air gaps between metal lines in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 11B), an IC device (e.g., the IC device 1600 of FIG. 12), or any other suitable component. In some embodiments, the IC package 1720 may include one or more metal layers with air gaps between metal lines, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 13, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example computing device 1800 that may include one or more metal layers with air gaps between metal lines in accordance with any of the embodiments disclosed herein. For example, any suitable ones of the components of the computing device 1800 may include a die (e.g., the die 1502 (FIG. 11B)) having one or more metal layers with air gaps between metal lines. Any one or more of the components of the computing device 1800 may include, or be included in, an IC device 1600 (FIG. 12). Any one or more of the components of the computing device 1800 may include, or be included in, an IC device assembly 1700 (FIG. 13).

A number of components are illustrated in FIG. 14 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 14, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an integrated circuit (IC) device including a first conductive structure that extends in a first direction; a second conductive structure that extends in the first direction, parallel to the first conductive structure; and a dielectric material between the first conductive structure and the second conductive structure, where the dielectric material surrounds an air gap between the first conductive structure and the second conductive structure.

Example 2 provides the IC device of example 1, where the dielectric material includes a first layer on the first conductive structure and a second layer on the second conductive structure, the air gap between the first layer and the second layer.

Example 3 provides the IC device of example 2, where the first layer has a width of less than 1 nanometer, and the second layer has a width of less than 1 nanometer.

Example 4 provides the IC device of any of the preceding examples, further including a dielectric layer over the first conductive structure, the second conductive structure, the dielectric material, and the air gap.

Example 5 provides the IC device of example 4, where the dielectric material has a height between the air gap and the dielectric layer of at least 5 nanometers.

Example 6 provides the IC device of example 4 or 5, where the first conductive structure and the second conductive structure are tapered in the direction of the dielectric layer.

Example 7 provides the IC device of any of examples 4-6, further including a conductive via extending through the dielectric layer and in contact with the first conductive structure, where the dielectric material is between the conductive via and the air gap.

Example 8 provides the IC device of any of the preceding examples, where the dielectric material includes aluminum.

Example 9 provides the IC device of any of the preceding examples, where the first conductive structure and the second conductive structure include ruthenium.

Example 10 provides the IC device of any of the preceding examples, where the first conductive structure and the second conductive structure have a center-to-center distance of less than 20 nanometers.

Example 11 provides an integrated circuit (IC) device including a device layer including a plurality of transistors; and a metal layer over the device layer, the metal layer including a first metal line that extends in a first direction; a second metal line that extends in the first direction, parallel to the first metal line; and a dielectric material between the first metal line and the second metal line, where the dielectric material surrounds an air gap between the first metal line and the second metal line.

Example 12 provides the IC device of example 11, where the metal layer is one of the first five metal layers over the device layer.

Example 13 provides the IC device of example 11 or 12, where the first metal line and the second metal line have a center-to-center distance of less than 20 nanometers.

Example 14 provides the IC device of any of examples 11-13, further including a second metal layer over the metal layer, the second metal layer including a third metal line that extends in a second direction perpendicular to the first direction; a fourth metal line that extends in the second direction; and additional dielectric material between the third metal line and the fourth metal line, where the additional dielectric material surrounds an air gap between the third metal line and the fourth metal line.

Example 15 provides the IC device of any of examples 11-14, where the dielectric material includes a first layer on the first metal line and a second layer on the second metal line, the air gap between the first layer and the second layer.

Example 16 provides the IC device of example 15, where the first layer has a width of less than 1 nanometer, and the second layer has a width of less than 1 nanometer.

Example 17 provides the IC device of any of examples 11-16, further including a dielectric layer over the first metal line, the second metal line, the dielectric material, and the air gap.

Example 18 provides the IC device of example 17, where the dielectric material has a height between the air gap and the dielectric layer of at least 5 nanometers.

Example 19 provides a method including providing a plurality of metal lines in a metal layer, a first of the metal lines and a second of the metal lines extending in parallel to each other and adjacent to each other; depositing a dielectric material along a first side of the first metal line and a second side of the second metal line, where an air gap in the dielectric material is between the first metal line and the second metal line; and depositing a dielectric layer over the plurality of metal lines, where the air gap is under the dielectric layer.

Example 20 provides the method of example 19, where providing the plurality of metal lines includes subtractively etching the first metal line and the second metal line from a metal layer.

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. An integrated circuit (IC) device comprising:
a first conductive structure that extends in a first direction;
a second conductive structure that extends in the first direction, parallel to the first conductive structure; and
a dielectric material between the first conductive structure and the second conductive structure, wherein the dielectric material surrounds an air gap between the first conductive structure and the second conductive structure.

2. The IC device of claim 1, wherein the dielectric material comprises a first layer on the first conductive structure and a second layer on the second conductive structure, the air gap between the first layer and the second layer.

3. The IC device of claim 2, wherein the first layer has a width of less than 1 nanometer, and the second layer has a width of less than 1 nanometer.

4. The IC device of claim 1, further comprising a dielectric layer over the first conductive structure, the second conductive structure, the dielectric material, and the air gap.

5. The IC device of claim 4, wherein the dielectric material has a height between the air gap and the dielectric layer of at least 5 nanometers.

6. The IC device of claim 4, wherein the first conductive structure and the second conductive structure are tapered in the direction of the dielectric layer.

7. The IC device of claim 4, further comprising a conductive via extending through the dielectric layer and in contact with the first conductive structure, wherein the dielectric material is between the conductive via and the air gap.

8. The IC device of claim 1, wherein the dielectric material comprises aluminum.

9. The IC device of claim 1, wherein the first conductive structure and the second conductive structure comprise ruthenium.

10. The IC device of claim 1, wherein the first conductive structure and the second conductive structure have a center-to-center distance of less than 20 nanometers.

11. An integrated circuit (IC) device comprising:
a device layer comprising a plurality of transistors; and
a metal layer over the device layer, the metal layer comprising:
a first metal line that extends in a first direction;
a second metal line that extends in the first direction, parallel to the first metal line; and
a dielectric material between the first metal line and the second metal line, wherein the dielectric material surrounds an air gap between the first metal line and the second metal line.

12. The IC device of claim 11, wherein the metal layer is one of the first five metal layers over the device layer.

13. The IC device of claim 11, wherein the first metal line and the second metal line have a center-to-center distance of less than 20 nanometers.

14. The IC device of claim 11, further comprising a second metal layer over the metal layer, the second metal layer comprising:
a third metal line that extends in a second direction perpendicular to the first direction;
a fourth metal line that extends in the second direction; and
additional dielectric material between the third metal line and the fourth metal line, wherein the additional dielectric material surrounds an air gap between the third metal line and the fourth metal line.

15. The IC device of claim 11, wherein the dielectric material comprises a first layer on the first metal line and a second layer on the second metal line, the air gap between the first layer and the second layer.

16. The IC device of claim 15, wherein the first layer has a width of less than 1 nanometer, and the second layer has a width of less than 1 nanometer.

17. The IC device of claim 11, further comprising a dielectric layer over the first metal line, the second metal line, the dielectric material, and the air gap.

18. The IC device of claim 17, wherein the dielectric material has a height between the air gap and the dielectric layer of at least 5 nanometers.

19. A method comprising:
providing a plurality of metal lines in a metal layer, a first of the metal lines and a second of the metal lines extending in parallel to each other and adjacent to each other;
depositing a dielectric material along a first side of the first metal line and a second side of the second metal line, wherein an air gap in the dielectric material is between the first metal line and the second metal line; and
depositing a dielectric layer over the plurality of metal lines, wherein the air gap is under the dielectric layer.

20. The method of claim 19, wherein providing the plurality of metal lines comprises subtractively etching the first metal line and the second metal line from a metal layer.
